(19) United States
(12) Patent Application Publication
(10) Pub. No.: US 2025/0370341 A1
(43) Pub. Date: Dec. 4, 2025

(54) CHEMICALLY AMPLIFIED PHOTORESIST COMPOSITION INCLUDING COPOLYMER ADDITIVE AND METHOD OF MANUFACTURING INTEGRATED CIRCUIT DEVICE BY USING THE SAME

(71) Applicant: SAMSUNG ELECTRONICS CO., LTD., Suwon-si (KR)

(72) Inventors: Sungkun KANG, Suwon-si (KR); Juhyeon Park, Suwon-si (KR)

(73) Assignee: SAMSUNG ELECTRONICS CO., LTD., Suwon-si (KR)

(21) Appl. No.: 18/975,606

(22) Filed: Dec. 10, 2024

(30) Foreign Application Priority Data
May 31, 2024 (KR) 10-2024-0071819

(51) Int. Cl. G03F 7/039; G03F 7/004; G03F 7/42

(52) U.S. Cl. CPC G03F 7/0392; G03F 7/0043; G03F 7/0045; G03F 7/0048; G03F 7/427

(57) ABSTRACT

Provided is a photoresist composition including a chemically amplified polymer, a photoacid generator (PAG), a copolymer additive including a Group-14 element, and a solvent, wherein the copolymer additive includes repeating units satisfying

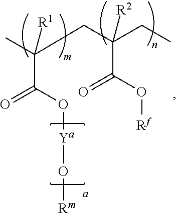

where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group including at least one Group-14 element, R^{f} is a group including a plurality of fluorine atoms (F), a is 0 or 1, and m/(m+n) and n/(m+n) are each 0.05 to 0.95.

### CROSS-REFERENCE TO RELATED APPLICATION

This application claims priority to Korean Patent Application No. 10-2024-0071819, filed on May 31, 2024, in the Korean Intellectual Property Office, the disclosure of which is incorporated by reference herein in its entirety.

### BACKGROUND

### 1. Field

Embodiments of the to a photoresist composition and a method of manufacturing an integrated circuit device by using the photoresist composition, and more particularly, to a chemically amplified photoresist composition, which includes a copolymer additive, and a method of manufacturing an integrated circuit device by using the chemically amplified photoresist composition.

### 2. Description of Related Art

Along with the advancement of the electronics industry, there is an increasing demand for low-power, high-performance devices. To satisfy the demand for low-power, high-performance devices, semiconductor circuits have become smaller and more complex. However, as sizes of patterns intended to be implemented decrease, the loss of photoresist patterns used as etch masks during the process of etching increases, and as aspect ratios of photoresist patterns increase, pattern defects, such as pattern leaning and pattern collapse, are likely to be generated. Accordingly, there is a limit to increasing the thicknesses of photoresist patterns. Therefore, there is a need to develop a material and a process, which are capable of securing etch selectivity in an etching process for manufacturing an integrated circuit device, even when the size and thickness of a photoresist pattern decreases.

### SUMMARY

One or more embodiments provide a photoresist composition that may provide a photoresist pattern capable of securing etch selectivity in an etching process for manufacturing an integrated circuit device even when the size and thickness of the photoresist pattern decrease.

One or more embodiments also provide a method of manufacturing an integrated circuit device, which has improved process stability and improved reliability by using a photoresist composition that may provide a photoresist pattern capable of securing etch selectivity in an etching process for manufacturing an integrated circuit device even when the size and thickness of the photoresist pattern decrease.

According to an aspect of one or more embodiments, there is provided a photoresist composition including a chemically amplified polymer, a photoacid generator (PAG), a copolymer additive including a Group-14 element, and a solvent, wherein the copolymer additive includes repeating units satisfying

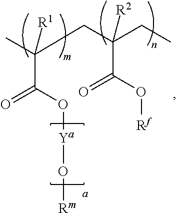

where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group including at least one Group-14 element, R^{f} is a group including a plurality of fluorine atoms (F), a is 0 or 1, and m/(m+n) and n/(m+n) are each 0.05 to 0.95.

According to another aspect of one or more embodiments, there is provided a photoresist composition including a chemically amplified polymer, a photoacid generator (PAG), a copolymer additive including silicon (Si) or tin (Sn), and a solvent, wherein the copolymer additive includes repeating units satisfying

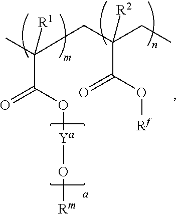

where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group including at least one trialkylsilyl group or at least one trialkylstannyl group, R^{f} is a perfluoroalkyl group, or a fluorinated hydrocarbon group including a perfluoroalkyl group as a substituent, a is 0 or 1, and m/(m+n) and n/(m+n) are each 0.05 to 0.95.

According to still another aspect of one or more embodiments, there is provided a method of manufacturing an integrated circuit device, the method including forming a device layer on a substrate, forming a photoresist film on the device layer by using a photoresist composition, the photoresist composition including a chemically amplified polymer, a photoacid generator (PAG), a copolymer additive including a Group-14 element, and a solvent, pre-treating the photoresist film such that the copolymer additive moves to an exposed surface side of the photoresist film to form a surface self-segregation layer, exposing a partial region of the pre-treated photoresist film to light, and forming a photoresist pattern including the surface self-segregation layer, in a non-light-exposed region of the photoresist film, by removing the light-exposed region of the photoresist film by using a developer, wherein, in the forming of the photoresist film, the copolymer additive includes repeating units satisfying

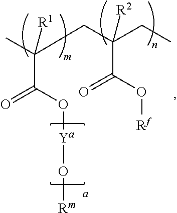

where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group including at least one Group-14 element, R^{f} is a group including a plurality of fluorine atoms (F), a is 0 or 1, and m/(m+n) and n/(m+n) are each 0.05 to 0.95.

### BRIEF DESCRIPTION OF DRAWINGS

Embodiments will be more clearly understood from the following detailed description taken in conjunction with the accompanying drawings in which:

FIG. 1 is a flowchart illustrating a method of manufacturing an integrated circuit device, according to one or more embodiments; and

FIGS. 2A, 2B, 2C, 2D, 2E, 2F, 2G, and 2H are cross-sectional views respectively illustrating a sequence of processes of a method of manufacturing an integrated circuit device, according to one or more embodiments.

### DETAILED DESCRIPTION

Hereinafter, one or more embodiments will be described in detail with reference to the accompanying drawings. Like components are denoted by like reference numerals throughout the specification, and repeated descriptions thereof are omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

A photoresist composition according to one or more embodiments includes a chemically amplified polymer, a photoacid generator (PAG), a copolymer additive including a Group-14 element, and a solvent. The copolymer additive includes repeating units represented by General Formula 1 shown below. For example, the copolymer additive includes a first repeating unit indicated by m and a second repeating unit indicated by n, as shown in General Formula 1.

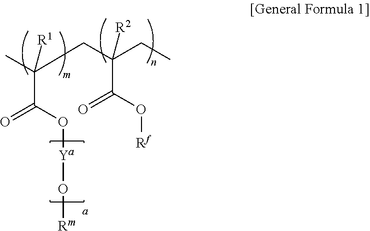

In General Formula 1, R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group including at least one Group-14 element, R^{f} is a group including a plurality of fluorine atoms (F), a is 0 or 1, and m/(m+n) and n/(m+n) are each 0.05 to 0.95.

Unless otherwise stated, the term “substituted” used herein refers to including at least one substituent, for example, a halogen atom (for example, a F atom, a C1 atom, a Br atom, or an I atom), a hydroxyl group, an amino group, a thiol group, a carboxyl group, a carboxylate group, an ester group, an amide group, a nitrile group, a sulfide group, a disulfide group, a nitro group, a C1-C20 alkyl group, a C3-C20 cycloalkyl group, a C2-C20 alkenyl group, a C1-C20 alkoxy group, a C2-C20 alkenoxy group, a C2-C30 aryl group, a C6-C30 aryloxy group, a C7-C30 alkylaryl group, or a C7-C30 alkylaryloxy group.

In some one or more embodiments, in General Formula 1, R¹ and R² may each be a hydrogen atom or a methyl group.

In General Formula 1, R^{m} is a protecting group including at least one Group-14 element according to the International Union of Pure and Applied Chemistry (IUPAC) periodic table. For example, R^{m} may include at least one element selected from silicon (Si), tin (Sn), germanium (Ge), and carbon (C).

In one or more embodiments, R^{m} may include at least one group selected from a trialkylsilyl group, a trialkylstannyl group, a trialkylgermyl group, and a tertiary alkyl group. For example, R^{m} may include at least one trialkylsilyl group or at least one trialkylstannyl group.

In one or more embodiments, R^{m} may include a substituted or unsubstituted C1-C10 alkyl group that may include a heteroatom, a substituted or unsubstituted C6-C10 aryl group that may include a heteroatom, a substituted or unsubstituted C7-C10 arylalkyl group that may include a heteroatom, or an ester group (—O—C(═O)—).

In one or more embodiments, R^{m} may include a linear, branched, or cyclic hydrocarbon group. For example, the hydrocarbon group of R^{m} may include: an alkyl group, such as a methyl group, an ethyl group, an n-propyl group, an isopropyl group, an n-butyl group, or a t-butyl group; a monovalent saturated cycloaliphatic hydrocarbon group, such as a cyclopropyl group, a cyclopentyl group, a cyclohexyl group, a cyclopropylmethyl group, a 4-methylcyclohexyl group, a cyclohexylmethyl group, a norbornyl group, or an adamantyl group; an alkenyl group, such as a vinyl group, an allyl group, a propenyl group, a butenyl group, or a hexenyl group; a monovalent unsaturated cycloaliphatic hydrocarbon group, such as a cyclohexenyl group; an aryl group, such as a phenyl group or a naphthyl group; a heteroaryl group, such as a thienyl group; or an aralkyl group, such as a benzyl group, a 1-phenylethyl group, or a 2-phenylethyl group.

In one or more embodiments, some of hydrogen atoms that are included in the hydrocarbon group of R™ may each be substituted with a group containing a heteroatom, such as oxygen, sulfur, nitrogen, or a halogen atom (for example, a fluorine atom).

R^{m} may include a hydroxyl moiety, a cyano moiety, a carbonyl moiety, an ether bond, an ester bond, a sulfonic acid ester bond, a carbonate bond, a lactone ring, a sultone ring, a carboxylic anhydride, or a haloalkyl moiety.

At least some of carbon atoms that are included in the hydrocarbon group of R^{m} may each be substituted with a Group-14 element, for example, Si, Sn, or Ge.

In one or more embodiments, in General Formula 1, R^{m} may be a Si-containing group and may be one selected from the following structures.

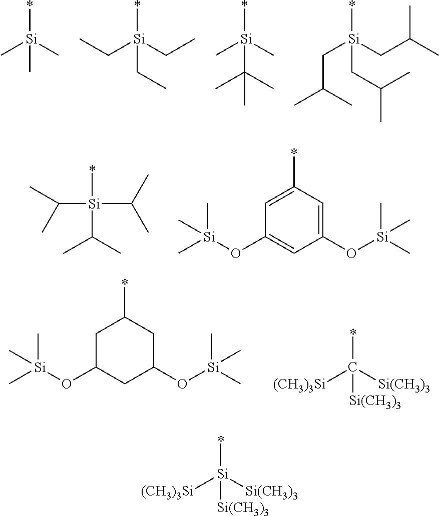

In the above structures, “*” represents a binding site.

In one or more embodiments, in General Formula 1, R^{m} may be a Sn-containing group and may be one selected from the following structures.

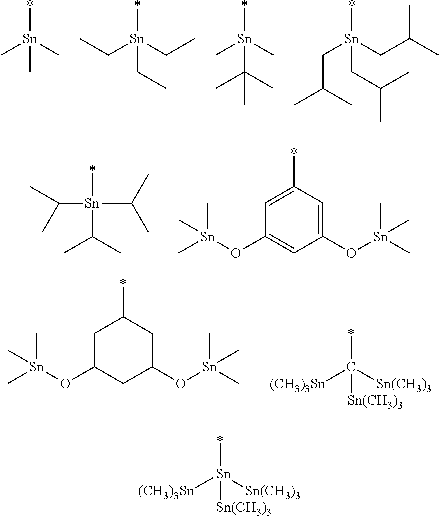

In the above structures, “*” represents a binding site.

In one or more embodiments, in General Formula 1, R^{m} may be a Ge-containing group and may be one selected from the following structures.

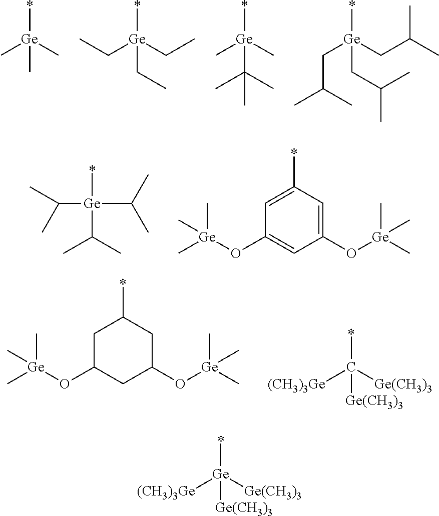

In the above structures, “*” represents a binding site.

In one or more embodiments, in General Formula 1, R^{m} may be a Ge-containing group and may be one selected from the following structures.

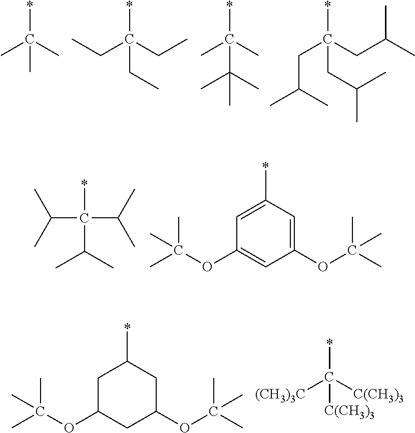

In the above structures, “*” represents a binding site.

In one or more embodiments, in General Formula 1, Y^{a} may be a C1-C5 substituted or unsubstituted alkylene group. For example, Y^{a} may be —(CH₂)ₖ— (wherein k is an integer of 1 to 5).

In one or more embodiments, in General Formula 1, Y^{a} may be a substituted or unsubstituted C5-C20 bivalent monocyclic or condensed-cyclic alicyclic hydrocarbon group or a substituted or unsubstituted C6-C20 bivalent monocyclic or condensed-cyclic aromatic hydrocarbon group. For example, Y^{a} may be one selected from the following structures.

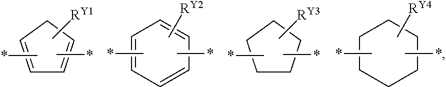

In the above structures, r may be an integer of 0 to 2, and R^{Y1}, R^{Y2}, R^{Y3}, and R^{Y4} may each be a substituted or unsubstituted C1-C10 alkyl group, a substituted or unsubstituted cyclopropyl group, a substituted or unsubstituted cyclopentyl group, or a substituted or unsubstituted cyclohexyl group. In the above structures, “*” represents a binding site.

In General Formula 1, R^{f} may be a perfluoroalkyl group, or a fluorinated hydrocarbon group including a perfluoroalkyl group as a substituent. For example, R^{f} may be a trifluoromethyl group, or a fluorinated hydrocarbon group including a trifluoromethyl group as a substituent. In one or more embodiments, R^{f} may include at least one trifluoromethyl group (—CF₃) and at least one hydroxyl group (—OH).

In one or more embodiments, in General Formula 1, R^{f} may be a C1-C25 fluorinated hydrocarbon group including a fluoroalkyl group as a substituent. For example, in General Formula 1, R^{f} may be a C1-C15 fluorinated hydrocarbon group including a perfluoroalkyl group as a substituent.

In one or more embodiments, in General Formula 1, R^{f} may include at least one selected from *—CF₃, *—CH₂CF₃, *—CF₂CF₃, *—CH₂CH(CF₃)₂, *—(CH₂)₃CF₃, *—(CF₂)₃CF₃, —C(CF₃)₂OH, *—CH₂C(CF₃)₂OH, *—CH₂OCH₂C(CF₃)₂OH, and *—CH(CH₃)CH₂C(CF₃)₂OH.

In one or more embodiments, in General Formula 1, R^{f} may be, but is not limited to, one selected from the following structures.

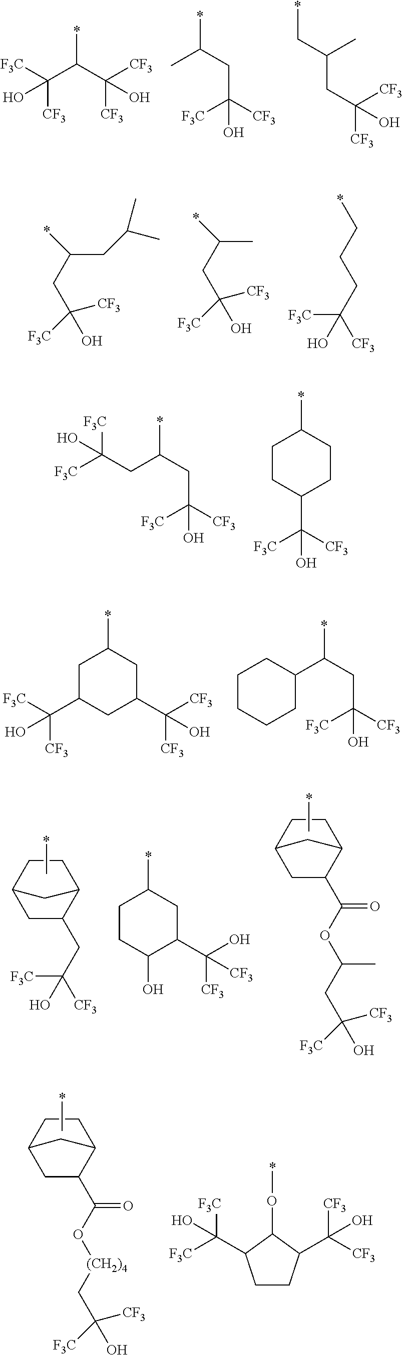

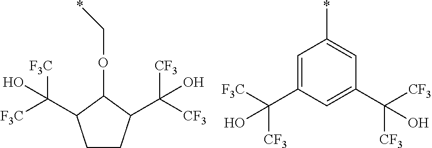

In the above structures, represents a binding site.

In the copolymer additive of the photoresist composition according to one or more embodiments, the amount of the first repeating unit indicated by m may be equal to or less than the amount of the second repeating unit indicated by n, in General Formula 1. For example, in the copolymer additive, the first repeating unit indicated by m may be present in an amount of about 1 mol % to about 50 mol % or about 5 mol % to about 20 mol %, but the inventive concept is not limited thereto.

The copolymer additive of the photoresist composition according to one or more embodiments may further include a third repeating unit represented by General Formula 2.

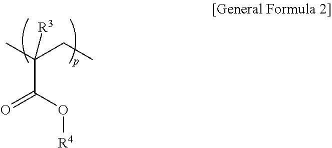

In General Formula 2, R³ is a hydrogen atom or a C1-C3 alkyl group, and R⁴ is an acid-labile protecting group or a lactone-containing group.

When the copolymer additive further includes the third repeating unit indicated by p in General Formula 2, n/(n+m+p), m/(n+m+p), and p/(n+m+p) are each 0.05 to 0.4 in the copolymer additive.

In one or more embodiments, in General Formula 2, R³ may be a hydrogen atom or a methyl group.

In one or more embodiments, R⁴ may include an acid-labile protecting group. For example, R⁴ may be an acid-labile protecting group selected from a substituted or unsubstituted t-butyl group and a C1-C30 substituted or unsubstituted tertiary alicyclic group.

When R⁴ includes an acid-labile protecting group, R⁴ may be one selected from the following structures.

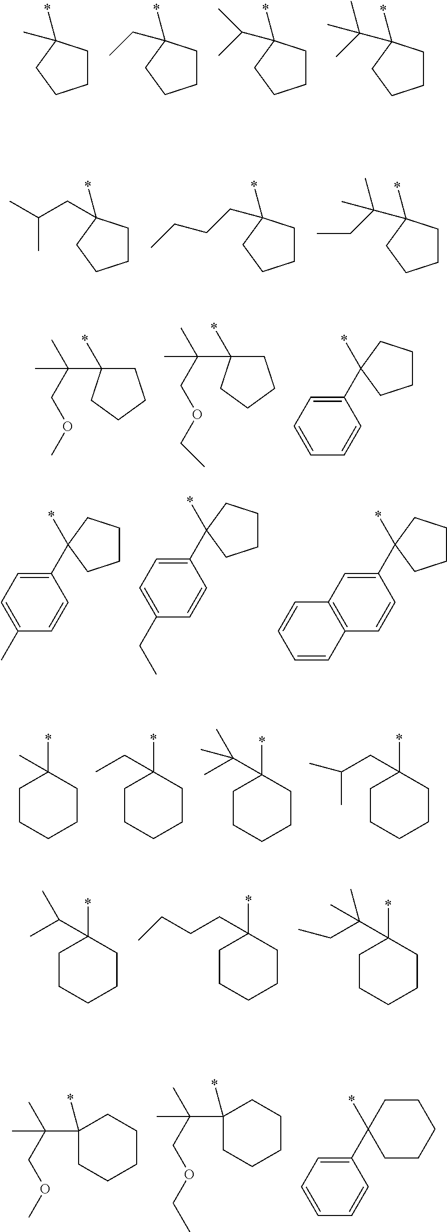

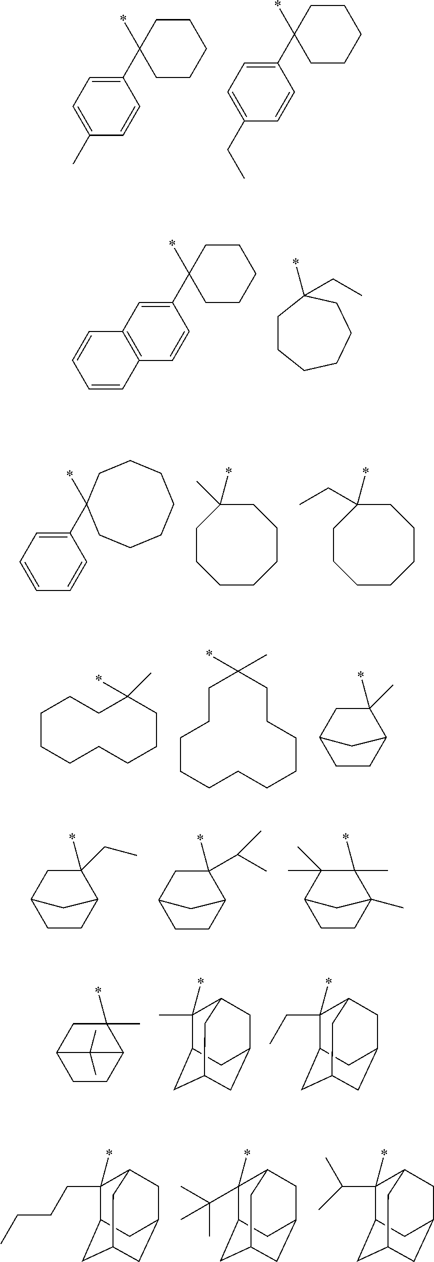

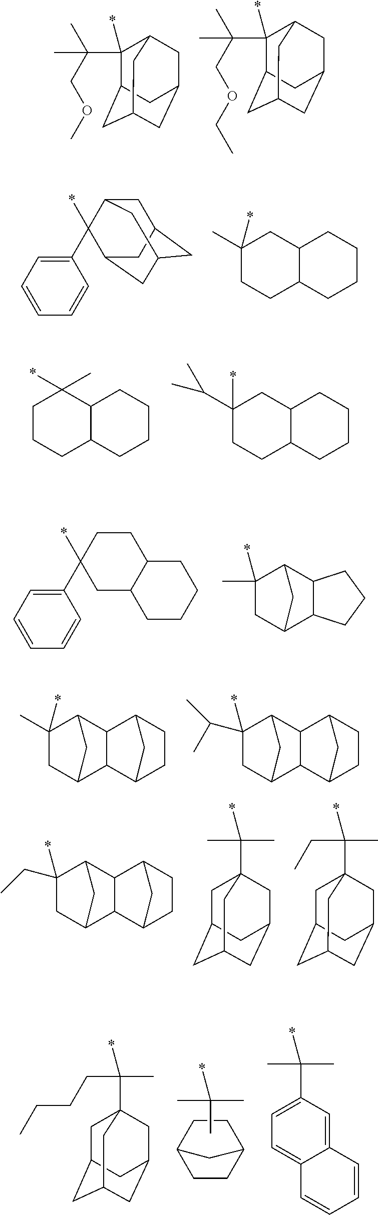

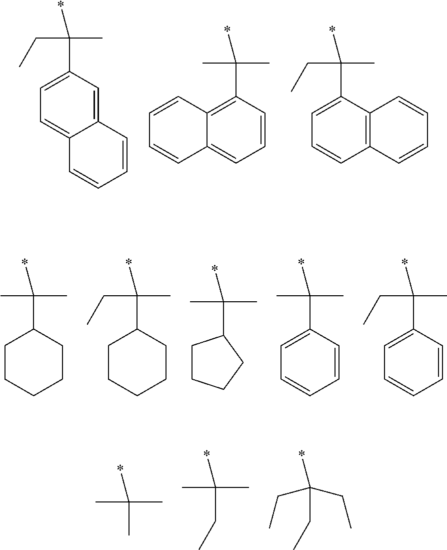

In the above structures, “*” represents a binding site.

In one or more embodiments, R⁴ may include a lactone-containing group.

When R⁴ includes a lactone-containing group, R⁴ may be one selected from the following structures.

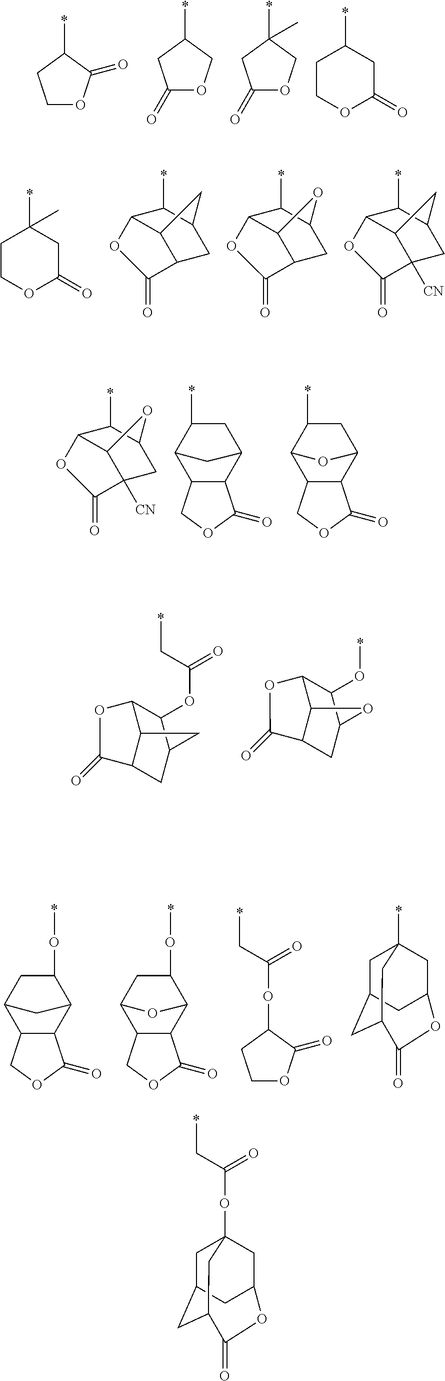

In the photoresist composition according to one or more embodiments, when the copolymer additive further includes the third repeating unit indicated by p in General Formula 2, the amount of the first repeating unit indicated by m may be equal to or less than the sum of the respective amounts of the second repeating unit indicated by n and the third repeating unit indicated by p. For example, when the copolymer additive further includes the third repeating unit indicated by p in General Formula 2, the first repeating unit indicated by m may be present in an amount of about 1 mol % to about 50 mol % or about 5 mol % to about 20 mol % in the copolymer additive, but the inventive concept is not limited thereto.

In the photoresist composition according to one or more embodiments, the copolymer additive may further include the third repeating unit indicated by p in General Formula 2, thereby further improving process efficiency in a lithography process using an ArF excimer laser (193 nm) or an extreme ultraviolet (EUV) light source.

In the photoresist composition according to one or more embodiments, the copolymer additive may have a weight-average molecular weight of about 1,000 to about 50,000 or about 5,000 to about 20,000. The copolymer additive may have a polydispersity of about 2.0 or less or about 1.5 or less.

In the photoresist composition according to one or more embodiments, the amount of the copolymer additive may be appropriately selected by taking into account the quality or the like of a photoresist pattern intended to be obtained from the photoresist composition. In some one or more embodiments, the copolymer additive may be present in an amount of about 0.001 wt % to about 20 wt %, for example, about 0.01 wt % to about 10 wt % or about 0.01 wt % to about 5 wt %, based on the total weight of the photoresist composition, but the inventive concept is not limited thereto. In the photoresist composition according to one or more embodiments, the copolymer additive may be present in an amount of about 0.01 wt % to about 50 wt %, for example, about 0.1 wt % to about 20 wt % or about 0.1 wt % to about 10 wt %, based on the total weight of the chemically amplified polymer, but the inventive concept is not limited thereto.

In the photoresist composition according to one or more embodiments, the chemically amplified polymer may include a polymer including a repeating unit capable of having a change in solubility in a developer due to the action of an acid. The chemically amplified polymer may include a block copolymer or a random copolymer. In some one or more embodiments, the chemically amplified polymer may include a positive photoresist. The positive photoresist may include a resist for a KrF excimer laser (248 nm), a resist for an ArF excimer laser (193 nm), a resist for an F₂ excimer laser (157 nm), or a resist for EUV (13.5 nm).

In some one or more embodiments, the chemically amplified polymer may include a repeating unit, which is decomposed by the action of an acid and thus increases solubility in an alkaline developer. In some one or more embodiments, the chemically amplified polymer may include a repeating unit, which is decomposed by the action of an acid and thus generates phenolic acid or a BrØnsted acid corresponding thereto. For example, the chemically amplified polymer may include a first main repeating unit that is derived from hydroxystyrene or a hydroxystyrene derivative. The hydroxystyrene derivative may include compounds in which a hydrogen atom at the α-position of hydroxystyrene is substituted with a C1-C5 alkyl group or a C1-C5 alkyl halide group, and derivatives thereof. For example, the first main repeating unit may be derived from 3-hydroxystyrene, 4-hydroxystyrene, 5-hydroxy-2-vinylnaphthalene, or 6-hydroxy-2-vinylnaphthalene.

In some one or more embodiments, the chemically amplified polymer may have a structure in which the first main repeating unit derived from hydroxystyrene or a hydroxystyrene derivative is copolymerized with at least one second main repeating unit having an acid-labile protecting group. The at least one second main repeating unit may include a (meth)acrylate-based polymer. For example, the at least one second main repeating unit may include polymethylmethacrylate (PMMA), poly(t-butylmethacrylate), poly(methacrylic acid), poly(norbornylmethacrylate), or a binary or ternary copolymer of main repeating units of the (meth)acrylate-based polymers set forth above.

In some one or more embodiments, the chemically amplified polymer may include a blend of a first polymer having the first main repeating unit and a second polymer having the at least one second main repeating unit.

The acid-labile group, which may be included in the at least one second main repeating unit, may include, but is not limited to, tert-butoxycarbonyl (t-BOC) group, an isonorbornyl group, a 2-methyl-2-adamantyl group, a 2-ethyl-2-adamantyl group, a 3-tetrahydrofuranyl group, a 3-oxocyclohexyl group, a γ-butyllactone-3-yl group, a mevaloniclactone group, a γ-butyrolactone-2-yl group, a 3-methyl-γ-butyrolactone-3-yl group, a 2-tetrahydropyranyl group, a 2-tetrahydrofuranyl group, a 2,3-propylenecarbonate-1-yl group, a 1-methoxyethyl group, a 1-ethoxyethyl group, a 1-(2-methoxyethoxy)ethyl group, a 1-(2-acetoxyethoxy)ethyl group, a t-buthoxycarbonylmethyl group, a methoxymethyl group, an ethoxymethyl group, a trimethoxysilyl group, or a triethoxysilyl group.

In some one or more embodiments, the chemically amplified polymer may further include at least one of a third main repeating unit, which has an acrylate derivative substituent including a hydroxyl group (—OH), and a fourth main repeating unit having a protecting group substituted with fluorine.

The chemically amplified polymer may have a weight-average molecular weight of about 1,000 to about 500,000. The chemically amplified polymer may be present in an amount of about 1 wt % to about 25 wt % in the photoresist composition, based on the total weight of the photoresist composition. When the amount of the chemically amplified polymer is less than about 1 wt %, the coating of the photoresist composition may not be smoothly performed. When the amount of the chemically amplified polymer is greater than about 25 wt %, it may be difficult to uniformly coating the photoresist composition because the viscosity of the photoresist composition excessively increases.

In the photoresist composition according to one or more embodiments, the PAG may generate an acid when exposed to light of one selected from a KrF excimer laser (248 nm), an ArF excimer laser (193 nm), an F2 excimer laser (157 nm), and an EUV light source (13.5 nm). In some one or more embodiments, the PAG may include a material generating a relatively strong acid, which has an acid dissociation constant (that is, pKa) of at least about −20 and less than about 1, due to exposure to light. The PAG may include, for example, triarylsulfonium salts, diaryliodonium salts, sulfonates, or a mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the photoresist composition according to one or more embodiments, the PAG may be present in an amount of about 0.1 wt % to about 5.0 wt % based on the total weight of the chemically amplified polymer, but the inventive concept is not limited thereto.

In one or more embodiments, the photoresist composition according to one or more embodiments may further include a basic quencher.

The basic quencher is a compound capable of trapping an acid in a non-light-exposed region of a photoresist film, when the acid generated from a photo-decomposable compound of the photoresist composition according to one or more embodiments or the acid generated from the PAG of the photoresist composition diffuses into the non-light-exposed region. The basic quencher may be included in the photoresist composition according to one or more embodiments, thereby suppressing a diffusion rate of the acid.

In some one or more embodiments, the basic quencher may include primary aliphatic amines, secondary aliphatic amines, tertiary aliphatic amines, aromatic amines, heteroaromatic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. For example, the basic quencher may include, but is not limited to, triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof.

In some one or more embodiments, the basic quencher may include a photo-decomposable base. The photo-decomposable base may include a compound generating an acid due to exposure to light and neutralizing an acid before exposure to light. When the photo-decomposable base is decomposed by exposure to light, the photo-decomposable base may lose a function of trapping an acid. Therefore, when a certain region of a photoresist film formed from a chemical amplified photoresist composition, which includes the basic quencher including the photo-decomposable base, is exposed to light, the photo-decomposable base may lose alkalinity in a light-exposed region of the photoresist film and may trap an acid in a non-light-exposed region of the photoresist film, thereby suppressing an acid from diffusing from the light-exposed region into the non-light-exposed region.

The photo-decomposable base may include a carboxylate or sulfonate salt of a photo-decomposable cation. For example, the photo-decomposable cation may form a complex with an anion of a C1-C20 carboxylic acid. The carboxylic acid may include, but is not limited to, for example, formic acid, acetic acid, propionic acid, tartaric acid, succinic acid, cyclohexylcarboxylic acid, benzoic acid, or salicylic acid.

In the photoresist composition according to one or more embodiments, the basic quencher may be present in an amount of about 0.01 wt % to about 5.0 wt % based on the total weight of the chemical amplified polymer, but embodiments are not limited thereto.

In the photoresist composition according to one or more embodiments, the solvent may include an organic solvent. In some one or more embodiments, the solvent may include at least one of ethers, alcohols, glycol ethers, aromatic hydrocarbon compounds, ketones, and esters. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These solvents may be used alone or in combination of at least two thereof. In one or more embodiments, the amount of the solvent in the photoresist composition may be adjusted such that solids are present in an amount of about 3 wt % to about 20 wt % in the photoresist composition.

In some one or more embodiments, the photoresist composition according to one or more embodiments may further include a surfactant.

The surfactant may be selected from, but is not limited to, fluoroalkylbenzene sulfonate, fluoroalkyl carboxylate, fluoroalkyl polyoxyethylene ether, fluoroalkyl ammonium iodide, fluoroalkyl betaine, fluoroalkyl sulfonate, diglycerin tetrakis(fluoroalkyl polyoxyethylene ether), fluoroalkyl trimethyl ammonium salts, fluoroalkyl aminosulfonate, polyoxyethylene nonylphenyl ether, polyoxyethylene octylphenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonate, and alkyl diphenyl ether disulfonate. The surfactant may be present in an amount of about 0.001 wt % to about 0.1 wt % based on the total weight of the chemically amplified polymer, but embodiments are not limited thereto.

The photoresist composition according to one or more embodiments includes the copolymer additive, and the copolymer additive includes the first repeating unit that includes the protecting group, R^{m}, including at least one Group-14 element, for example, at least one atom of Si, Sn, Ge, or C. The protecting group, R^{m}, of the first repeating unit may include a hydrophobic group. Therefore, when a photolithography process is performed by using the photoresist composition according to one or more embodiments, the copolymer additive, which includes R^{m} including a Group-14 element and R^{f} that is a group including a plurality of fluorine atoms, in a photoresist film obtained from the photoresist composition moves to an exposed surface of the photoresist film, and thus, self-segregation of a layer may occur in the photoresist film. As a result, a surface self-segregation layer, which includes the copolymer additive including R^{m}, may be formed at the exposed surface of the photoresist film.

When a certain region of the photoresist film is exposed to light, the copolymer additive in the surface self-segregation layer may change to be hydrophilic in the light-exposed region of the photoresist film. Accordingly, when the photoresist film is developed, the surface self-segregation layer in the light-exposed region, together with other portions in the light-exposed region, may be removed by a developer. Therefore, after a photoresist pattern including a non-light-exposed region of the photoresist film is formed, pattern defects due to residues of the surface self-segregation layer in the light-exposed region may be prevented or reduced.

Portions of the surface self-segregation layer in the non-light-exposed region of the photoresist film may remain in the photoresist pattern including the non-light-exposed region of the photoresist film. Therefore, when an etching target film under the photoresist pattern is etched by using the photoresist pattern as an etch mask, the etch resistance of the photoresist pattern may be improved by materials that include Group-14 elements of the copolymer additive, for example, elements including Si, Sn, Ge, or C, in the surface self-segregation layer.

For example, in the first repeating unit indicated by m in General Formula 1, when the protecting group, R^{m}, includes Group-14 elements, such as Si or Sn, the photoresist pattern may be plasma-treated by using plasma of an oxygen-containing gas, thereby further enhancing the etch resistance of the photoresist pattern. For example, when the photoresist pattern is plasma-treated by using plasma of an O₂ or O₃ gas while the surface self-segregation layer including a Group-14 element, such as Si or Sn, is present at the surface of the photoresist pattern, Si or Sn in the surface self-segregation layer reacts with O₂ plasma or O₃ plasma to form a compound having relatively low volatility and having relatively low reactivity with etching gases used in a subsequent etching process. As a result, the etch resistance of the photoresist pattern may further improve.

Therefore, when an etching process for manufacturing an integrated circuit device is performed, a photoresist pattern obtained from the photoresist composition according to one or more embodiments may be used as an etch mask, thereby significantly enhancing etch resistance in the etching process. Therefore, even when the size and thickness of the photoresist pattern is reduced, sufficient etch selectivity may be secured in the etching process for manufacturing an integrated circuit device, and process stability and reliability in the process of manufacturing an integrated circuit device may improve.

To prepare the copolymer additive of the photoresist composition according to one or more embodiments, related reaction processes may be used. For example, to synthesize the copolymer additive including the first repeating unit indicated by m and the second repeating unit indicated by n, as shown in General Formula 1, a first monomer, which is required to obtain the first repeating unit indicated by m, and a second monomer, which is required to obtain the second repeating unit indicated by n, may be mixed with each other at an intended molar ratio by using an organic solvent, for example, tetrahydrofuran (THF), as a solvent, and a radical polymerization reaction may be performed at room temperature for a day by using 2,2-azobisisobutyronitrile (AIBN) as an initiator. Next, a resulting product of the polymerization reaction may be precipitated by using a n-hexane solution, followed by drying the precipitates, thereby obtaining the intended copolymer additive.

In one or more embodiments, the first monomer required to obtain the first repeating unit indicated by m in General Formula 1 may include, but is not limited to, one selected from the following monomers.

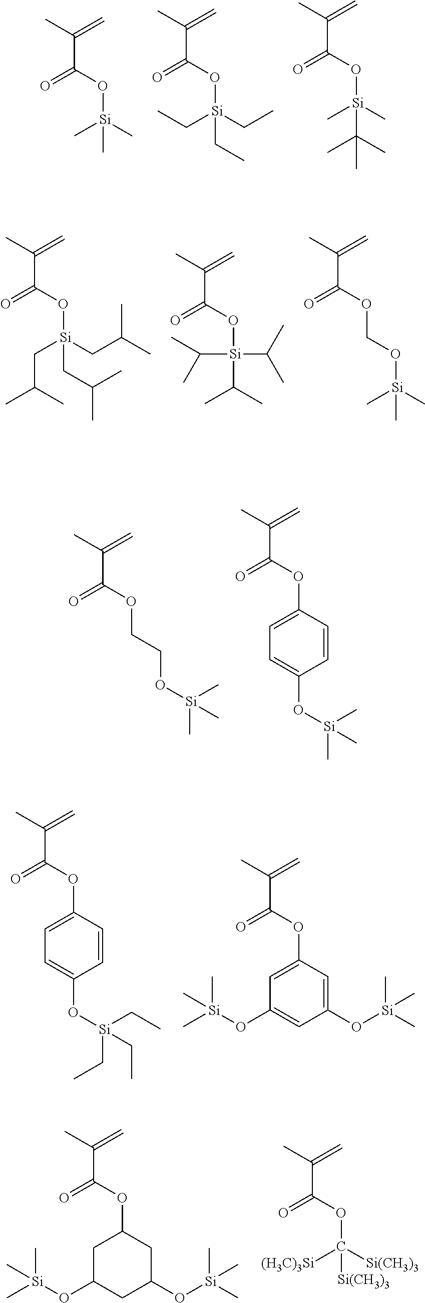

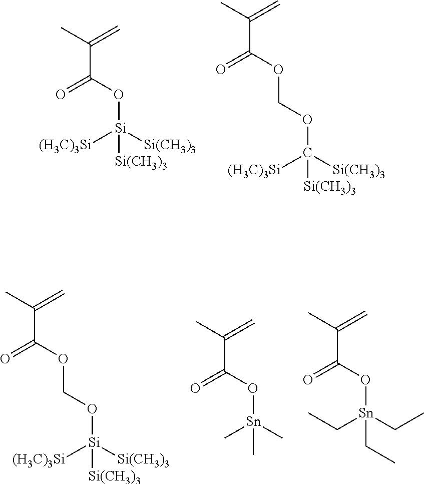

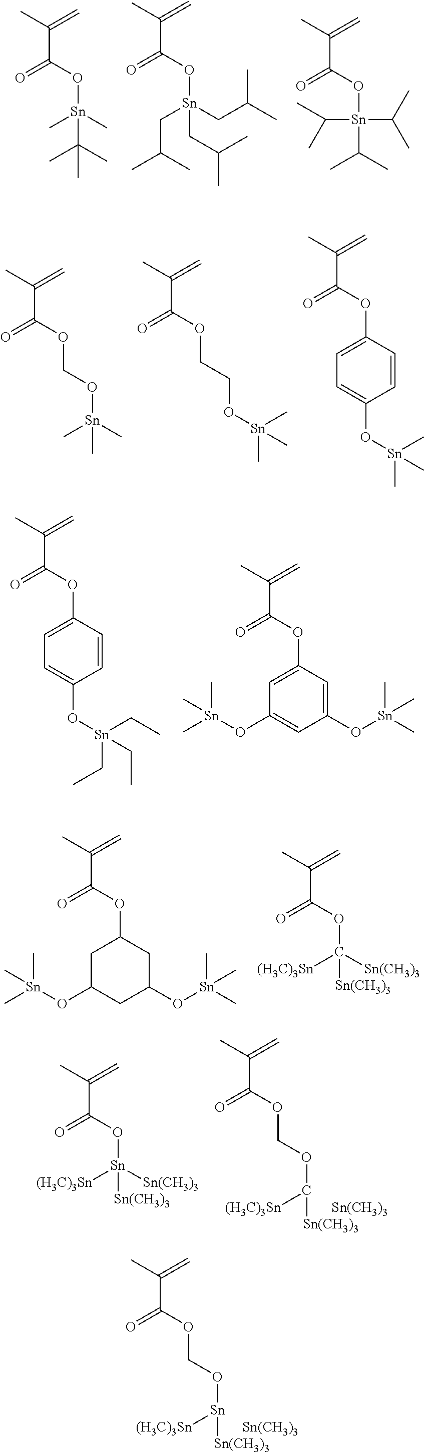

In one or more embodiments, the second monomer required to obtain the second repeating unit indicated by n in General Formula 1 may include, but is not limited to, one selected from the following monomers.

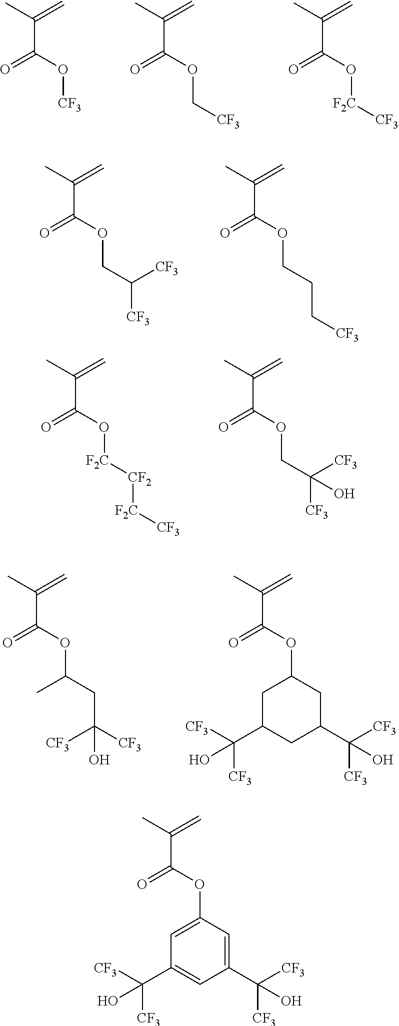

The various monomers shown above may be easily synthesized by a related method. For example, to obtain a trimethylstannyl methacrylate monomer, trimethylstannyl chloride, methacrylate, and a toluene solvent may be reacted together in a 4-neck flask equipped with a thermometer for temperature adjustment of reaction, a reflux condenser, a stirring means, and a monomer adding device, thereby obtaining the intended monomer. A process of synthesizing a trimethylsilyl methacrylate monomer may be similar to the process of synthesizing the trimethylstannyl methacrylate monomer. However, a reaction temperature for synthesizing the trimethylsilyl methacrylate monomer may be lower than the reaction temperature for synthesizing the trimethylstannyl methacrylate monomer.

Hereinafter, an example of a method of manufacturing an integrated circuit device, according to one or more embodiments, is described with reference to the accompanying drawings.

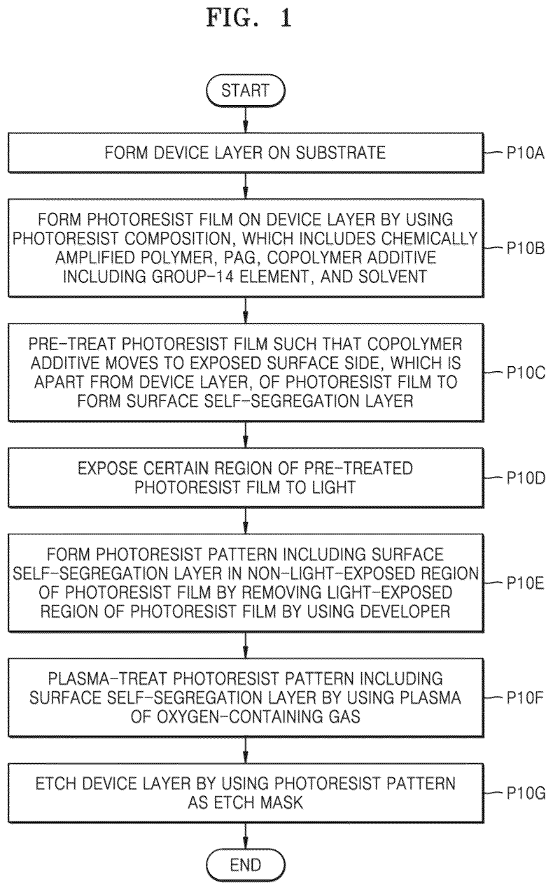

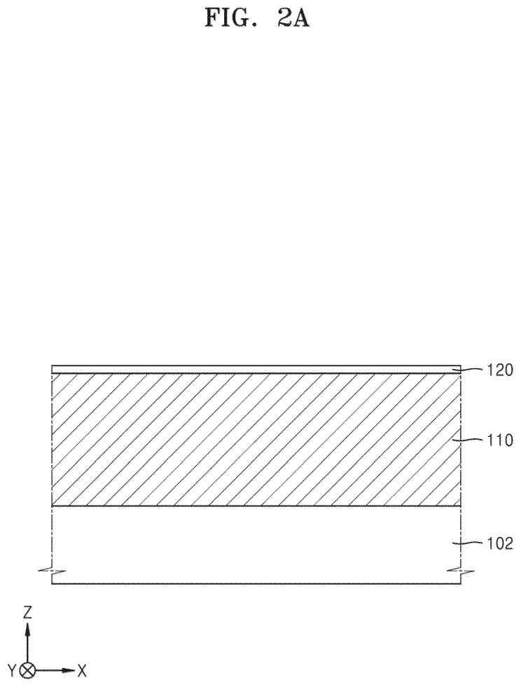

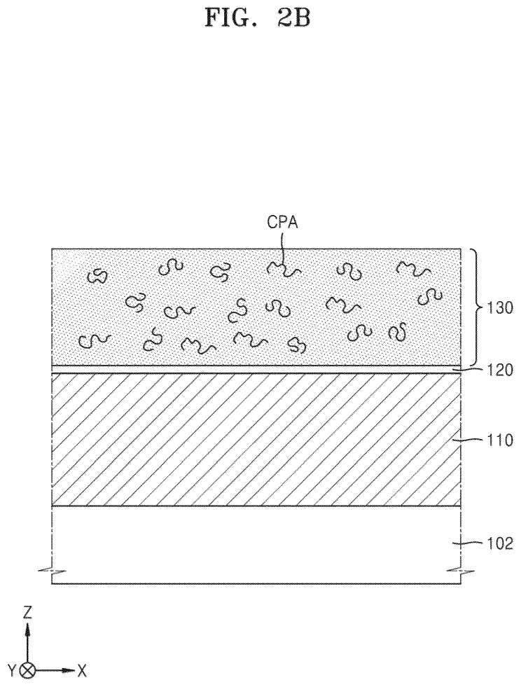

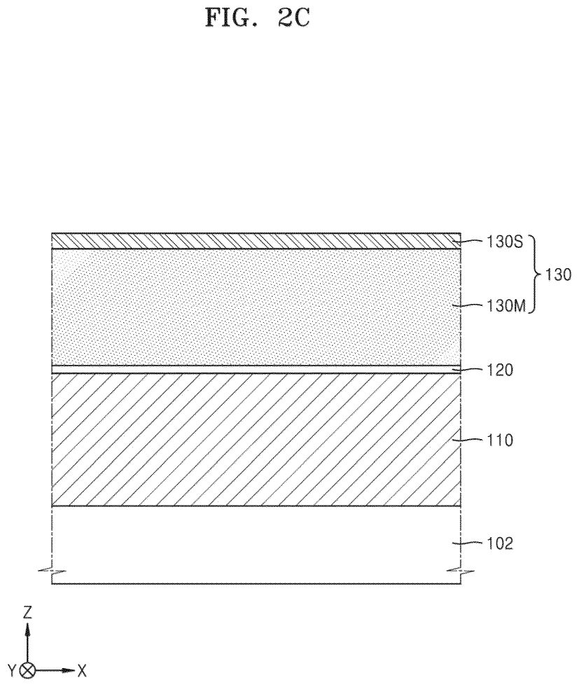

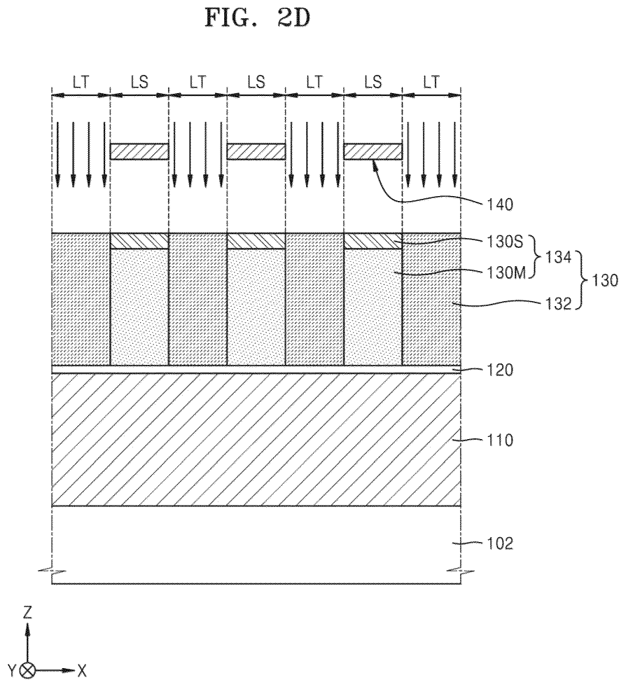

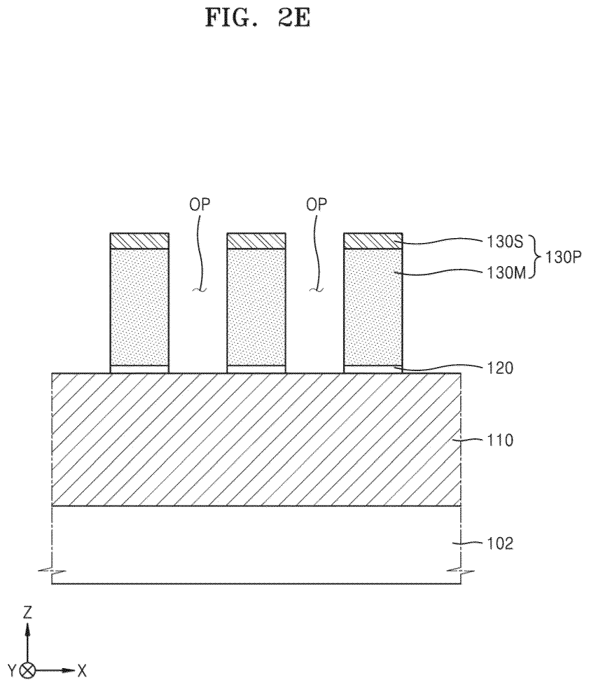

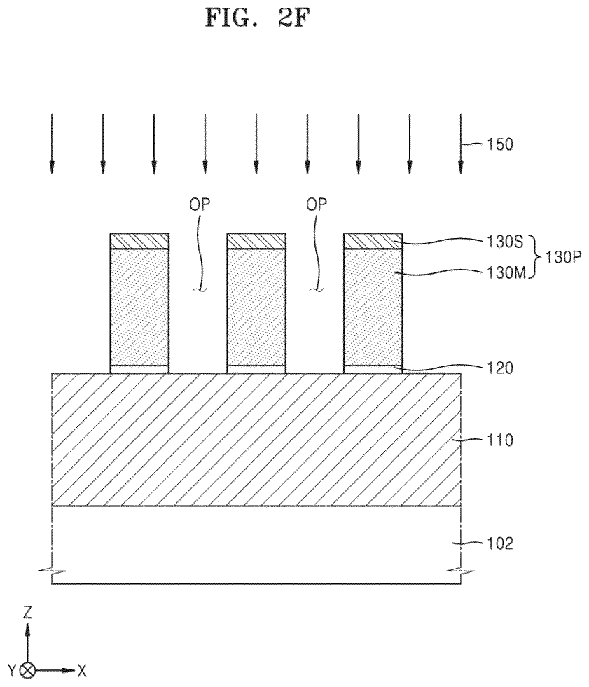

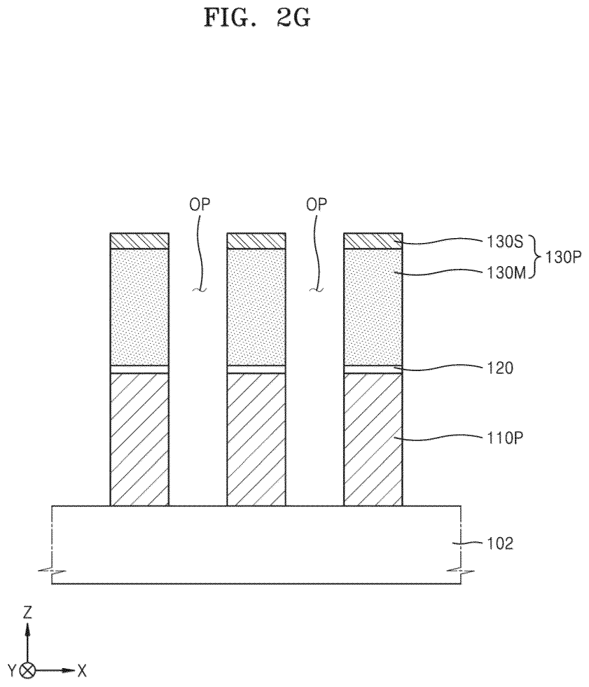

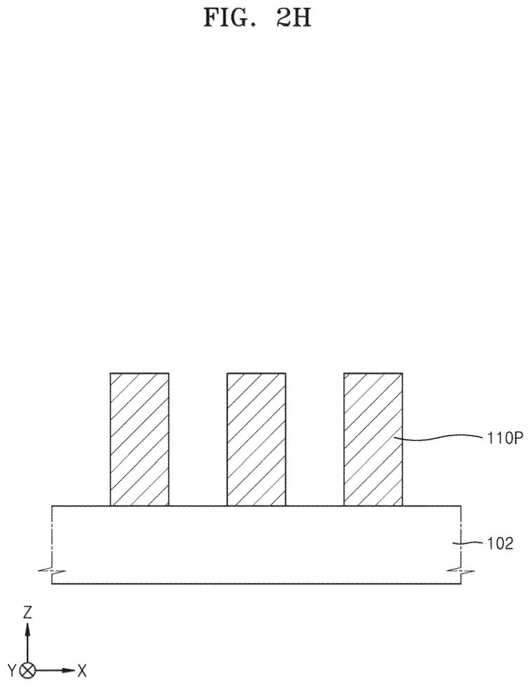

FIG. 1 is a flowchart illustrating a method of manufacturing an integrated circuit device, according to one or more embodiments. FIGS. 2A to 2H are cross-sectional views respectively illustrating a sequence of processes of a method of manufacturing an integrated circuit device, according to one or more embodiments. Hereinafter, a method of manufacturing an integrated circuit device, according to one or more embodiments, is described with reference to FIGS. 1 and 2A to 2H.

Referring to FIGS. 1 and 2A, in process P10A, a device layer 110 may be formed on a substrate 102. Next, a resist lower film 120 may be formed on the device layer 110.

The substrate 102 may include a semiconductor substrate. In one or more embodiments, the semiconductor substrate may include a semiconductor element, such as Si or Ge. In one or more embodiments, the semiconductor substrate may include a compound semiconductor, such as silicon germanium (SiGe), silicon carbide (SiC), gallium arsenide (GaAs), indium arsenide (InAs), or indium phosphide (InP). In one or more embodiments, the substrate 102 may have a silicon-on-insulator (SOI) structure.

The substrate 102 may be an area in which a semiconductor device including a plurality of individual devices of various types is formed. The plurality of individual devices may include various microelectronic devices, for example, a metal-oxide-semiconductor field effect transistor (MOSFET) such as a complementary metal-insulator-semiconductor (CMOS) transistor, system large-scale integration (LSI), an image sensor such as a CMOS imaging sensor (CIS), a micro-electro-mechanical system (MEMS), an active element, a passive element, and the like. In one or more embodiments, the substrate 102 may include a semiconductor die area for forming a memory semiconductor chip or a logic circuit chip. For example, the semiconductor die area may be an area for forming a volatile memory semiconductor chip, such as dynamic random access memory (DRAM) or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

The device layer 110 may be a film required to configure devices that are to be formed in the semiconductor die area. In one or more embodiments, the device layer 110 may include an insulating film or a conductive film. For example, the device layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

The resist lower film 120 may be arranged between the device layer 110 and a photoresist film 130 (see FIG. 2B) that is formed in a subsequent process and may prevent issues generated because irradiation rays reflected from under the photoresist film 130 are scattered to the photoresist film 130.

In one or more embodiments, the resist lower film 120 may include a developable bottom anti-reflective coating (DBARC) film. The DBARC film may control the diffuse reflection of light from a light source used in a light-exposure process or may absorb reflected light from the device layer 110 under the DBARC film. In one or more embodiments, the DBARC film may include an organic anti-reflective coating (ARC) material for a light source, such as a KrF excimer laser, an ArF excimer laser, an F₂ excimer laser, or an EUV light source. In some one or more embodiments, the DBARC film may include an organic component having a light-absorption structure. The light-absorption structure may include, for example, a hydrocarbon compound having a structure in which one or more benzene rings are fused.

In some one or more embodiments, the resist lower film 120 may include a carbon-containing film. For example, the resist lower film 120 may include a carbon film, a doped carbon film, or an amorphous carbon layer (ACL). The doped carbon film may include a dopant including oxygen (O), Si, nitrogen (N,) tungsten (W), boron (B), iodin (I), chlorine (Cl), or a combination thereof.

The resist lower film 120 may have a thickness of about 1 nm to about 100 nm. To form the resist lower film 120, a plasma enhanced chemical vapor deposition (PECVD) process or an atomic layer deposition (ALD) process may be used, but embodiments are not limited thereto.

Referring to FIGS. 1 and 2B, in process P10B, the photoresist film 130 may be formed on the device layer 110 by using a photoresist composition, which includes a chemically amplified polymer, a PAG, a copolymer additive CPA including a Group-14 element, and a solvent. Regarding the photoresist composition, a reference may be made to the above description of the photoresist composition according to one or more embodiments. In FIG. 2B, the copolymer additive, among the components constituting the photoresist film 130, is indicated as CPA.

To form the photoresist film 130, the photoresist composition according to one or more embodiments may be coated on the resist lower film 120. The coating set forth above may be performed by a method, such as spin coating, spray coating, dip coating, or the like. Directly after the formation of the photoresist film 130, the copolymer additive CPA may be non-uniformly dispersed in the photoresist film 130.

Referring to FIGS. 1 and 2C, in process P10C, the photoresist film 130 may be pre-treated such that the copolymer additive CPA moves to an exposed surface side, which is spaced apart from the device layer 110 and the resist lower film 120, of the photoresist film 130 to form a surface self-segregation layer 130S.

The pre-treatment process of the photoresist film 130 may include a soft-bake process of the photoresist film 130. The soft-bake process of the photoresist film 130 may be performed at a temperature of about 50° C. to about 300° C. for about 10 seconds to about 100 seconds. The thickness of the photoresist film 130 may be tens to hundreds of times the thickness of the resist lower film 120. The photoresist film 130 may have, but is not limited to, a thickness of about 100 nm to about 6 μm.

Because the copolymer additive CPA includes the hydrophobic protecting group, R^{m}, and R^{f} that is a group including a plurality of fluorine atoms, as described with reference to General Formula 1, while the photoresist film 130 is being pre-treated, the copolymer additive CPA non-uniformly dispersed in the photoresist film 130 may move to the exposed surface side, which is apart from the device layer 110 and the resist lower film 120, of the photoresist film 130 to be away from the resist lower film 120 having a hydrophilic surface, and thus, self-segregation of a layer may occur such that the copolymer additive CPA in the photoresist film 130 is intensively distributed at the upper surface of the photoresist film 130. As a result, the photoresist film 130 may include the surface self-segregation layer 130S including the copolymer additive CPA, and a main resist layer 130M including no copolymer additive CPA.

While the soft-bake process is being performed for the pre-treatment of the photoresist film 130, the solvent in the photoresist film 130 may be volatilized simultaneously with the formation of the surface self-segregation layer 130S, and adhesion between the photoresist film 130 and the resist lower film 120 may be increased.

Referring to FIGS. 1 and 2D, in process P10D, a certain region of the photoresist film 130 that is pre-treated according to the process described with reference to FIG. 2C may be exposed to light. After the photoresist film 130 is exposed to light, the photoresist film 130 may include a light-exposed region 132 and a non-light-exposed region 134.

In the light-exposed region 132 of the photoresist film 130, an acid may be generated from the PAG, and polymers that are in the light-exposed region 132 of the photoresist film 130 and include an acid-labile protecting group may be deprotected by the acid.

The polymers, which are in the light-exposed region 132 and include an acid-labile protecting group, may include the chemically amplified polymer that is included in the photoresist film 130. Therefore, in the light-exposed region 132, the acid-labile protecting group in the chemically amplified polymer may be decomposed by the acid, and thus, the chemically amplified polymer may be deprotected. In addition, when the copolymer additive CPA in the surface self-segregation layer 130S includes the third repeating unit of General Formula 2 and R⁴ in the third repeating unit of General Formula 2 includes an acid-labile protecting group, R⁴ may be decomposed, by the acid, from the third repeating unit of General Formula 2 in the surface self-segregation layer 130S in the light-exposed region 132, and thus, the third repeating unit of General Formula 2 in the copolymer additive CPA may be deprotected. Accordingly, in the light-exposed region 132 of the photoresist film 130, the copolymer additive CPA in the surface self-segregation layer 130S may change to be hydrophilic. Therefore, when the photoresist film 130 is developed in a subsequent process described below with reference to FIG. 2E, the surface self-segregation layer 130S in the light-exposed region 132, together with the main resist layer 130M in the light-exposed region 132, may be removed by a developer. Therefore, after a photoresist pattern 130P including the non-light-exposed region 134 of the photoresist film 130 is formed in the subsequent process described below with reference to FIG. 2E, a pattern defect due to residues of the surface self-segregation layer 130S in the light-exposed region 132 may be prevented or reduced.

To expose the certain region of the photoresist film 130 to light, a photomask 140, which has a plurality of light shielding areas LS and a plurality of light transmitting areas LT, may be aligned at a certain position over the photoresist film 130, and the certain region of the photoresist film 130 may be exposed to light through the plurality of light transmitting areas LT of the photomask 140. To expose the certain region of the photoresist film 130 to light, EUV light (13.5 nm), a KrF excimer laser (248 nm), an ArF excimer laser (193 nm), or an F₂ excimer laser (157 nm) may be used.

The non-light-exposed region 134 of the photoresist film 130 may include the surface self-segregation layer 130S including the copolymer additive CPA, and the main resist layer 130M including no copolymer additive CPA.

After the light-exposure process described with reference to FIG. 2D is performed, a post-exposure bake (PEB) process may be performed on the photoresist film 130 including the light-exposed region 132. The PEB process may be performed at a temperature of about 50° C. to about 300° C. By performing the PEB process, a chain of chemical reactions may occur due to the acid generated from the PAG in the light-exposed region 132, and as a result, the difference in solubility in a developer between the light-exposed region 132 and the non-light-exposed region 134 may be further increased.

Referring to FIGS. 1 and 2E, in process P10E, the light-exposed region 132 of the photoresist film 130 may be removed by using a developer, thereby forming the photoresist pattern 130P, which includes the surface self-segregation layer 130S and the main resist layer 130M in the non-light-exposed region 134 of the photoresist film 130. The developer may include a 2.38 wt % tetramethylammonium hydroxide (TMAH) solution.

The photoresist pattern 130P may include a plurality of openings OP. The device layer 110 may be exposed by removing portions of the resist lower film 120, the portions being exposed by the plurality of openings OP. In one or more embodiments, each of the plurality of openings OP may have, but is not limited to, a planar shape of a hole or a line.

As described above with reference to FIG. 2D, in the light-exposed region 132 of the photoresist film 130, the copolymer additive CPA in the surface self-segregation layer 130S may change to be hydrophilic. Therefore, when the photoresist film 130 is developed by using the developer, the surface self-segregation layer 130S in the light-exposed region 132, together with the main resist layer 130M in the light-exposed region 132, may be removed by the developer, and thus, after the photoresist pattern 130P is formed, pattern defects on the substrate 102 due to residues of the surface self-segregation layer 130S in the light-exposed region 132 may be prevented or reduced.

Because the photoresist pattern 130P includes the main resist layer 130M and the surface self-segregation layer 130S that covers the upper surface of the main resist layer 130M, when the device layer 110 is etched by using the photoresist pattern 130P as an etch mask in a subsequent process, the etch resistance of the photoresist pattern 130P may be improved by materials that include Group-14 elements, such as elements including Si, Sn, Ge, or C, in the copolymer additive CPA in the surface self-segregation layer 130S. When an etching process for manufacturing an integrated circuit device is performed, the photoresist pattern 130P may be used as an etch mask, thereby enhancing etch resistance in the etching process. Therefore, even when the size and thickness of the photoresist pattern 130P is reduced, sufficient etch selectivity may be secured in the etching process for manufacturing an integrated circuit device, and process stability and reliability in the process of manufacturing an integrated circuit device may improve.

Referring to FIGS. 1 and 2F, in process P10F, the photoresist pattern 130P including the surface self-segregation layer 130S may be plasma-treated by using plasma 150 of an oxygen-containing gas. The oxygen-containing gas may include, but is not limited to, an O₂ gas, an O₃ gas, or a combination thereof.

In the first repeating unit indicated by m in General Formula 1, when the protecting group, R^{m}, includes Group-14 elements, such as Si or Sn, the photoresist pattern 130P may be plasma-treated by using the plasma 150 of the oxygen-containing gas, thereby further enhancing the etch resistance of the photoresist pattern 130P. For example, when the photoresist pattern 130P is plasma-treated by using the plasma 150 of an O₂ or O₃ gas while the surface self-segregation layer 130S including a Group-14 element, such as Si or Sn, is present at the surface of the photoresist pattern 130P, Si or Sn in the surface self-segregation layer 130S reacts with O₂ plasma or O₃ plasma to form a compound having relatively low volatility and having relatively low reactivity with etching gases used in a subsequent etching process. As a result, the etch resistance of the photoresist pattern 130P may further improve.

Therefore, when an etching process for manufacturing an integrated circuit device is performed, the photoresist pattern 130P obtained from the photoresist composition according to one or more embodiments may be used as an etch mask, thereby significantly enhancing etch resistance in the etching process. Therefore, even when the size and thickness of the photoresist pattern 130P is reduced, sufficient etch selectivity may be secured in the etching process for manufacturing an integrated circuit device, and process stability and reliability in the process of manufacturing an integrated circuit device may improve.

The plasma 150 treatment process according to process P10F of FIG. 1, which is described with reference to FIG. 2F, may be omitted as needed.

Referring to FIGS. 1 and 2G, in process P10G, some regions of the device layer 110 may be etched through the plurality of openings OP by using the photoresist pattern 130P as an etch mask, thereby forming a device pattern 110P.

Referring to FIG. 2H, the photoresist pattern 130P and the resist lower film 120, which remain on or over the device pattern 110P, may be removed. To remove the photoresist pattern 130P and the resist lower film 120, for example, ashing and strip processes may be used.

According to the method of manufacturing an integrated circuit device, the method having been described with reference to FIGS. 1 and 2A to 2H, even when the size and thickness of the photoresist pattern 130P is reduced, sufficient etch selectivity may be secured in an etching process for manufacturing an integrated circuit device, and process stability and reliability in the process of manufacturing an integrated circuit device may improve.

While embodiments have been described with reference to the figures, it will be understood by those of ordinary skill in the art that various changes in form and details may be made therein without departing from the spirit and scope as defined by the following claims and their equivalents.

What is claimed is:

1. A photoresist composition comprising:
a chemically amplified polymer;
a photoacid generator (PAG);
a copolymer additive comprising a Group-14 element; and
a solvent,
wherein the copolymer additive comprises repeating units satisfying: 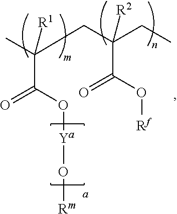
where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group comprising at least one Group-14 element, R^{f} is a group comprising a plurality of fluorine atoms (F), a is 0 or 1, and m/(m+n) and n/(m+n) are each 0.05 to 0.95.

2. The photoresist composition of claim 1, wherein R^{m} comprises at least one of a trialkylsilyl group, a trialkylstannyl group, a trialkylgermyl group, and a tertiary alkyl group.

3. The photoresist composition of claim 1, wherein R^{m} is one of: 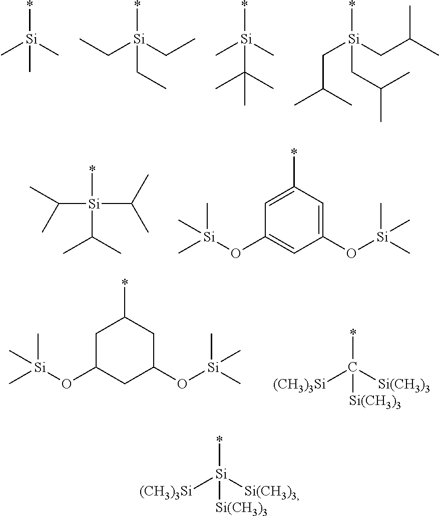
where * represents a binding site.

4. The photoresist composition of claim 1, wherein R^{m} is one of: 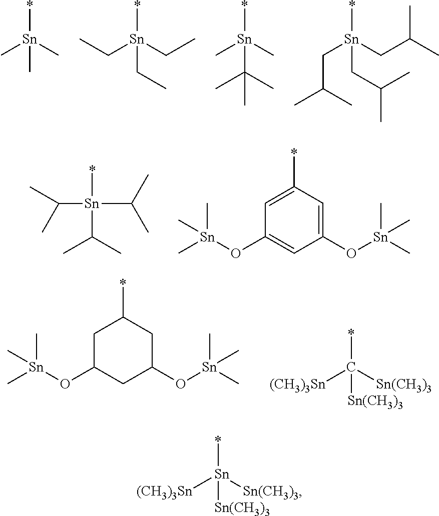
where * represents a binding site.

5. The photoresist composition of claim 1, wherein R^{m} is one of: 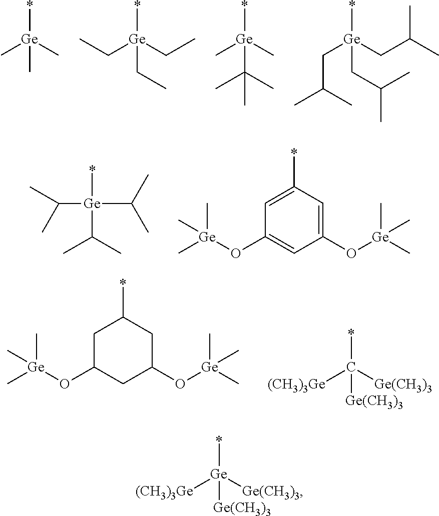
where * represents a binding site.

6. The photoresist composition of claim 1, wherein R^{m} is one of: 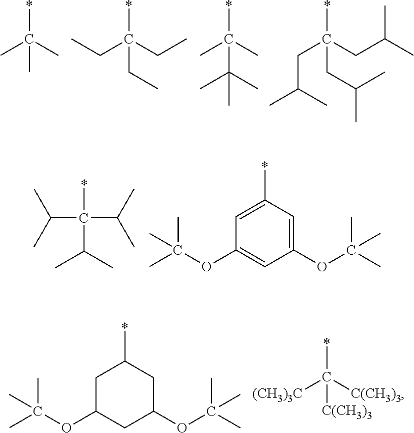
where * represents a binding site.

7. The photoresist composition of claim 1, wherein Y^{a} is a C1-C5 substituted or unsubstituted alkylene group, a C5-C20 bivalent monocyclic or condensed-cyclic alicyclic hydrocarbon group, or a C6-C20 bivalent monocyclic or condensed-cyclic aromatic hydrocarbon group.

8. The photoresist composition of claim 1, wherein Y^{a} is —(CH₂)ₖ, where k is an integer of 1 to 5.

9. The photoresist composition of claim 1, wherein Y^{a} is one of: 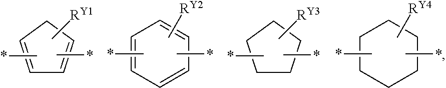
where r is an integer of 0 to 2, R^{Y1}, R^{Y2}, R^{Y3}, and R^{Y4} are each a C1-C10 alkyl group, a cyclopropyl group, a cyclopentyl group, or a cyclohexyl group, and * represents a binding site.

10. The photoresist composition of claim 1, wherein R^{f} is a perfluoroalkyl group, or a fluorinated hydrocarbon group comprising a perfluoroalkyl group as a substituent.

11. The photoresist composition of claim 1, wherein the copolymer additive further comprises a repeating unit satisfying: 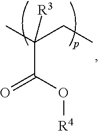
where R³ is a hydrogen atom (H) or a C1-C3 alkyl group, R⁴ is an acid-labile protecting group or a lactone-containing group, and, in the copolymer additive, n/(n+m+p), m/(n+m+p), and p/(n+m+p) are each 0.05 to 0.4.

12. A photoresist composition comprising:
a chemically amplified polymer;
a photoacid generator (PAG);
a copolymer additive comprising silicon (Si) or tin (Sn); and
a solvent,
wherein the copolymer additive comprises repeating units satisfying: 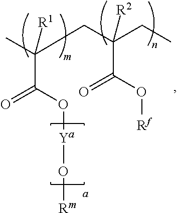
where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R™ is a protecting group comprising at least one trialkylsilyl group or at least one trialkylstannyl group, R^{f} is a perfluoroalkyl group, or a fluorinated hydrocarbon group comprising a perfluoroalkyl group as a substituent, a is 0 or 1, and m/(m+n) and n/(m+n) are each 0.05 to 0.95.

13. A method of manufacturing an integrated circuit device, the method comprising:
forming a device layer on a substrate;
forming a photoresist film on the device layer by using a photoresist composition, the photoresist composition comprising a chemically amplified polymer, a photoacid generator (PAG), a copolymer additive comprising a Group-14 element, and a solvent;
pre-treating the photoresist film such that the copolymer additive moves to an exposed surface side of the photoresist film to form a surface self-segregation layer;
exposing a partial region of the pre-treated photoresist film to light; and
forming a photoresist pattern comprising the surface self-segregation layer, in a non-light-exposed region of the photoresist film, by removing the light-exposed region of the photoresist film by using a developer,
wherein, in the forming of the photoresist film, the copolymer additive comprises repeating units satisfying: 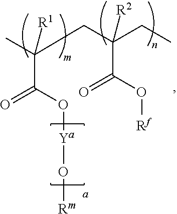
where R¹ and R² are each a hydrogen atom (H) or a C1-C3 alkyl group, Y^{a} is a substituted or unsubstituted C1-C20 bivalent linear hydrocarbon group, a substituted or unsubstituted C1-C20 bivalent cyclic hydrocarbon group, a substituted or unsubstituted C7-C20 bivalent alkylaryl group, or a carbonyl group, R^{m} is a protecting group comprising at least one Group-14 element,
R^{f} is a group comprising a plurality of fluorine atoms (F), a is 0 or 1, and m/(m+n) and n/(m+n) are each 0.05 to 0.95.

14. The method of claim 13, wherein R^{m} comprises at least one of a trialkylsilyl group, a trialkylstannyl group, a trialkylgermyl group, and a tertiary alkyl group.

15. The method of claim 13, wherein R^{m} is one of: 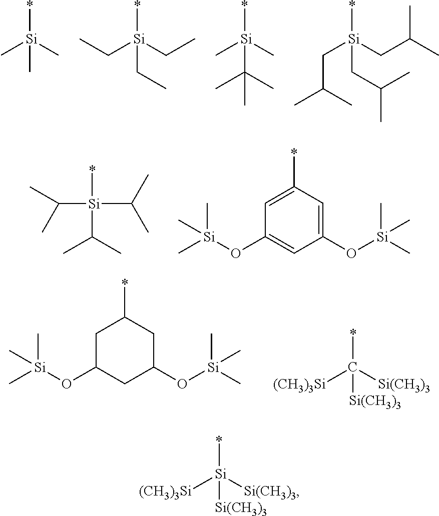
where * represents a binding site.

16. The method of claim 13, wherein R^{m} is one of: 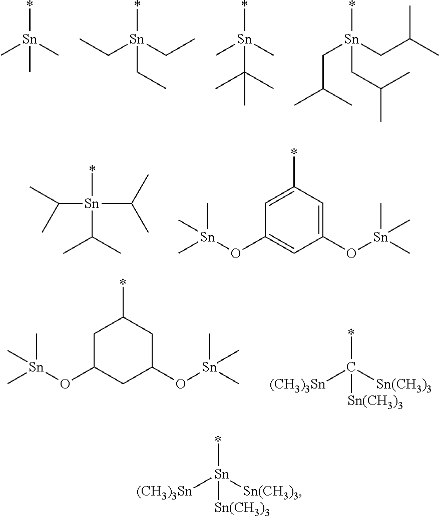
where * represents a binding site.

17. The method of claim 13, wherein Y^{a} is a C1-C5 substituted or unsubstituted alkylene group, a C5-C20 bivalent monocyclic or condensed-cyclic alicyclic hydrocarbon group, or a C6-C20 bivalent monocyclic or condensed-cyclic aromatic hydrocarbon group.

18. The method of claim 13, wherein R^{f} is a perfluoroalkyl group, or a fluorinated hydrocarbon group comprising a perfluoroalkyl group as a substituent.

19. The method of claim 13, wherein, in the forming of the photoresist film, the copolymer additive further comprises a repeating unit satisfying: 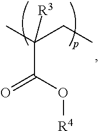
where R³ is a hydrogen atom (H) or a C1-C3 alkyl group, R⁴ is an acid-labile protecting group or a lactone-containing group, and, in the copolymer additive, n/(n+m+p), m/(n+m+p), and p/(n+m+p) are each 0.05 to 0.4.

20. The method of claim 13, further comprising:
after the forming of the photoresist pattern, plasma-treating the photoresist pattern comprising the surface self-segregation layer by using plasma of an oxygen-containing gas; and
etching the device layer by using the plasma-treated photoresist pattern.
